(19) United States
(12) Patent Application Publication
(10) Pub. No.: US 2026/0144053 A1
(43) Pub. Date: May 21, 2026

(54) BACKSIDE METAL CAPACITOR AND BITLINE

(71) Applicant: INTERNATIONAL BUSINESS MACHINES CORPORATION, Armonk, NY (US)

(72) Inventors: Klimentiy Shimanovich, Ramat Gan (IL); Rajiv Joshi, Yorktown Heights, NY (US); Ruilong Xie, Niskayuna, NY (US); Elazar Kachir, Tel Aviv (IL); Noam Jungmann, Holon (IL)

(21) Appl. No.: 18/953,645

(22) Filed: Nov. 20, 2024

(51) Int. Cl. H01L 23/522; H10B 10/00

(52) U.S. Cl. CPC H10W 20/496; H10B 10/125

(57) ABSTRACT

A semiconductor device includes a memory cell having a frontside and backside. A backside signal line is connected to the memory cell on the backside. A backside metal-insulator-metal (MIM) capacitor is disposed on the backside and has a first electrode connected to the backside signal line and a second electrode connected to an assist circuit that electrically boosts access operations of the memory cell.

### BACKGROUND

The present invention generally relates to semiconductor devices and processing methods, and more particularly to memory devices having a backside capacitor and bit lines below a memory cell.

Memory arrays based on static random access memory (SRAM) can employ unique SRAM cell structures with buried metal interconnects or assist circuits to support or even enhance read/write operations. Buried metals used for bit lines, word lines, or power supplies improve the performance and density of standard cells and mitigate increasing RC parasitic losses.

Read/write assist circuits include the use of a capacitor for the generation of extra voltage to be delivered to supply bit lines or word lines of SRAM cells. Such capacitors are implemented by two sets of front metal wires which create a capacitance through a coupling effect.

Silicon based capacitors, e.g., decap devices have been employed to provide a power boost. Decap devices are usually added in a design between power and ground rails to counter functional failures due to dynamic insulation resistance (IR) drop. Depending on the memory requirements like supply range, layout area, density of front metals, a type of assistance needed, several metal capacitors or decap devices need to be separately employed. These devices for the assist circuits consume additional layout area in the silicon and free front metal layers, which are prime limiting factors for dense memory designs.

The use of several metal capacitors requires a large area allocation in several metal layers. This puts additional density pressure on a frontside interconnect metal layers. It also increases the risk of shorts between neighboring metals due to process defects. The shorts can lead to increased power consumption, malfunctioning assist circuitry and local heating of the chip area.

### SUMMARY

In accordance with an embodiment of the present invention, a semiconductor device includes a memory cell having a frontside and backside. A backside signal line is connected to the memory cell on the backside. A backside metal-insulator-metal (MIM) capacitor is disposed on the backside and has a first electrode connected to the backside signal line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the backside signal line. The backside MIM capacitor and the backside signal line can share a footprint. The backside MIM capacitor can extend beyond a footprint of the backside signal line. The backside signal line can include a bit line. The backside signal line and a backside power line can share a same level on the backside of the semiconductor device.

In accordance with another embodiment of the present invention, a semiconductor device includes a memory cell having a frontside and backside. The memory cell includes a plurality of field effect transistors, and the field effect transistors include source/drain regions. Source/drain contacts are connected to the source/drain regions. A via is laterally connected to a source/drain contact and extends to the backside. A backside signal line is connected to the via on the backside. A backside MIM capacitor is disposed on the backside and has a first electrode connected to the backside signal line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the backside signal line. The backside MIM capacitor and the backside signal line can share a footprint. The backside MIM capacitor can extend beyond a footprint of the backside signal line. The backside signal line can include a bit line. The backside signal line and a backside power line can share a same level on the backside of the semiconductor device.

In accordance with another embodiment of the present invention, a semiconductor device includes a memory cell having a frontside and backside. The memory cell includes a plurality of field effect transistors and the field effect transistors include source/drain regions. Source/drain contacts are connected to the source/drain regions. A first via is laterally connected to a source/drain contact and extends to the backside. A bit line is connected to the first via on the backside. A second via is laterally connected to another source/drain contact and extends to the backside. A backside power line is connected to the second via on the backside on a same level as the bit line. A backside MIM capacitor is disposed on the backside and has a first electrode connected to the bit line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the bit line. The backside MIM capacitor and the bit line can share a footprint. The backside MIM capacitor can extend beyond a footprint of the bit line. The bit line and a backside power line can share a same level on the backside of the semiconductor device. The semiconductor device can include a static random access memory.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a schematic diagram with a simplified high level layout view of an SRAM cell over a metal-insulator-metal capacitor and an inset showing a complete layout view of half of the SRAM cell with X1, X2, Y1 and Y2 cross sectional lines in accordance with an embodiment of the present invention;

FIG. 2 shows cross-sectional views, taken at section lines X1, X2, Y1 and Y2, as shown in an inset of a layout view of semiconductor device showing a stack of layers from one or more nanosheets formed into gate structures and showing source/drain regions formed, in accordance with an embodiment of the present invention;

FIG. 3 shows cross-sectional views, taken at section lines X1, X2, Y1 and Y2, and an updated layout view in the inset, after middle of the line contacts are formed including source/drain contacts to the source/drain regions, in accordance with an embodiment of the present invention;

FIG. 4 shows cross-sectional views, taken at section lines X1, X2, Y1 and Y2, and an updated layout view in the inset, after openings are formed for vias and portions of the source/drain contacts are exposed, in accordance with an embodiment of the present invention;

FIG. 5 shows cross-sectional views, taken at section lines X1, X2, Y1 and Y2, and an updated layout view in the inset, after a spacer layer is formed within the openings formed for the vias, in accordance with an embodiment of the present invention;

FIG. 6 shows cross-sectional views, taken at section lines X1, X2, Y1 and Y2, and an updated layout view in the inset, after the spacer layer is patterned/recessed to access the source/drain contacts through openings or the vias, in accordance with an embodiment of the present invention;

FIG. 7 shows cross-sectional views, taken at section lines X1, X2, Y1 and Y2, and an updated layout view in the inset, after a via fill, back end of the line structures are formed, a carrier wafer is applied and the wafer is flipped to process a backside, in accordance with an embodiment of the present invention;

FIG. 8 shows cross-sectional views, taken at section lines X1, X2, Y1 and Y2, after a substrate has been removed to an etch stop layer, in accordance with an embodiment of the present invention;

FIG. 9 shows cross-sectional views, taken at section lines X1, X2, Y1 and Y2, after the etch stop layer has been removed and a semiconductor layer (remainder of the substrate) is recessed, in accordance with an embodiment of the present invention;

FIG. 10 shows cross-sectional views, taken at section lines X1, X2, Y1 and Y2, and an updated layout view in the inset, after an interlayer dielectric is formed and backside signal lines (e.g., bit lines) and power lines are formed therein, in accordance with an embodiment of the present invention;

FIG. 11 shows cross-sectional views, taken at section lines X1, X2, Y1 and Y2, after a metal-insulator-metal stack is formed on its own level on the backside, in accordance with an embodiment of the present invention;

FIG. 12 shows cross-sectional views, taken at section lines X1, X2, Y1 and Y2, and an updated layout view in the inset, after a metal-insulator-metal stack is patterned for a capacitor on the backside, in accordance with an embodiment of the present invention;

FIG. 13 shows cross-sectional views, taken at section lines X1, X2, Y1 and Y2, after forming contacts to the capacitor, vias and a backside interconnect layer, in accordance with an embodiment of the present invention; and

FIG. 14 is a schematic diagram showing an SRAM cell and an assist circuit connected to the capacitor, in accordance with an embodiment of the present invention.

### DETAILED DESCRIPTION

In accordance with embodiments of the present invention, devices and methods are described which include a backside metal-insulator-metal (MIM) capacitator. In an embodiment, a static random access memory (SRAM) cell includes a backside signal line (e.g., a bit line) which can be electrically coupled to the backside MIM capacitor to provide a performance improvement, e.g., writability enhancement. The SRAM cell design provides little resistance for the backside signal line which improves effective resistance-capacitance (RC) and writability. Further writability enhancement can be achieved by modulation of signals on the backside line through capacitive coupling to a bottom MIM capacitor plate which connects to an assist circuit. The backside MIM capacitor and backside signal line (e.g., bit line) reduce pressure density on metal layer interconnects on a frontside of a semiconductor device and reduce or eliminate the risk of short circuits (shorts).

In an embodiment, a semiconductor device includes a backside MIM capacitator where one electrode of the capacitor includes a bit line (e.g., a bit line electrode). The other electrode can be connected to an assist or boost circuitry. The two electrodes are separated by a dielectric layer (insulator). In an example, the assist circuit can be employed in an SRAM, and the backside MIM capacitor can be employed with a write assist circuit.

In accordance with an embodiment of the present invention, a semiconductor device includes a memory cell having a frontside and backside. A backside signal line is connected to the memory cell on the backside. A backside metal-insulator-metal (MIM) capacitor is disposed on the backside and has a first electrode connected to the backside signal line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the backside signal line. The backside MIM capacitor and the backside signal line can share a footprint. The backside MIM capacitor can extend beyond a footprint of the backside signal line. The backside signal line can include a bit line. The backside signal line and a backside power line can share a same level on the backside of the semiconductor device.

In accordance with another embodiment of the present invention, a semiconductor device includes a memory cell having a frontside and backside. The memory cell includes a plurality of field effect transistors, and the field effect transistors include source/drain regions. Source/drain contacts are connected to the source/drain regions. A via is laterally connected to a source/drain contact and extends to the backside. A backside signal line is connected to the via on the backside. A backside MIM capacitor is disposed on the backside and has a first electrode connected to the backside signal line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the backside signal line. The backside MIM capacitor and the backside signal line can share a footprint. The backside MIM capacitor can extend beyond a footprint of the backside signal line. The backside signal line can include a bit line. The backside signal line and a backside power line can share a same level on the backside of the semiconductor device.

In accordance with another embodiment of the present invention, a semiconductor device includes a memory cell having a frontside and backside. The memory cell includes a plurality of field effect transistors and the field effect transistors include source/drain regions. Source/drain contacts are connected to the source/drain regions. A first via is laterally connected to a source/drain contact and extends to the backside. A bit line is connected to the first via on the backside. A second via is laterally connected to another source/drain contact and extends to the backside. A backside power line is connected to the second via on the backside on a same level as the bit line. A backside MIM capacitor is disposed on the backside and has a first electrode connected to the bit line and a second electrode connected to an assist circuit that electrically boosts access operations of the memory cell.

In other embodiments, electrical connections can be made to the backside MIM capacitor through the backside to reduce a density of metal structures on the frontside. The backside MIM capacitor can be disposed directly on the bit line. The backside MIM capacitor and the bit line can share a footprint. The backside MIM capacitor can extend beyond a footprint of the bit line. The bit line and a backside power line can share a same level on the backside of the semiconductor device. The semiconductor device can include a static random access memory.

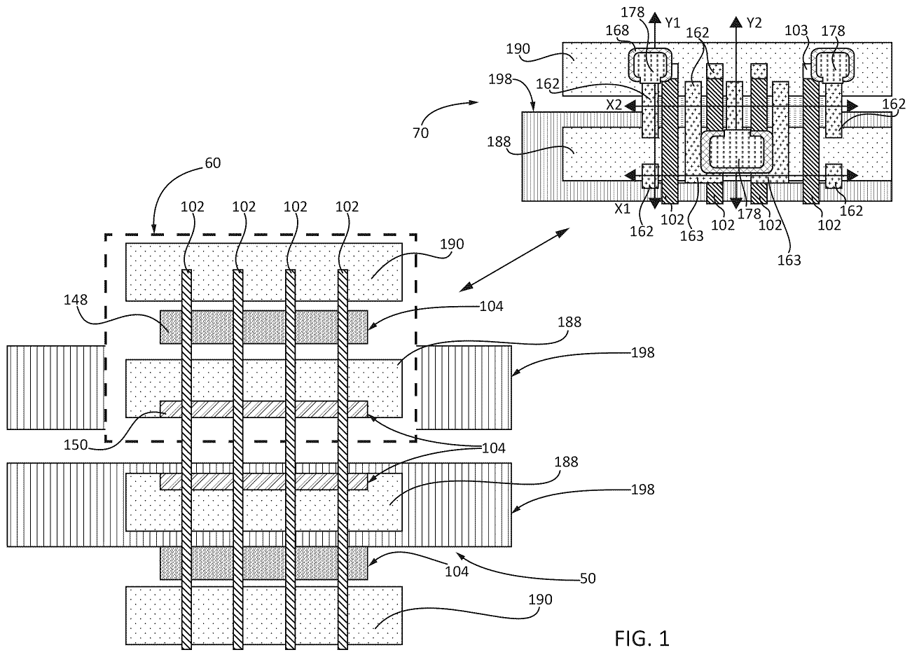

Referring now to the drawings in which like numerals represent the same or similar elements and initially to FIG. 1, a simplified layout view of an SRAM cell 50 is schematically shown. The SRAM includes a half portion 60 that is shown in a layout view in an inset 70. The inset 70 shows a complete layout view of the half portion 60 of the SRAM cell 50 with X1, X2, Y1 and Y2 cross sectional lines. The SRAM cell 50 is disposed over a metal-insulator-metal capacitor 198 and a power rails 190 as also shown in the inset 70. The SRAM cell 50 and the inset 70 includes gate lines 102 and active regions lines 104. Corresponding X1, X2, Y1 and Y2 views are depicted throughout the FIGS. Active region lines 104 represent source/drain (S/D) regions 148, 150 for transistor devices to be formed, and gate lines 102 are represented for such transistor devices. Transistor channels are formed on the active region lines 104 below the gate lines 102. Bit lines 188 are disposed over the MIM capacitor 198. Further description of the details of the structures in FIG. 1 will be described with reference to the following FIGS.

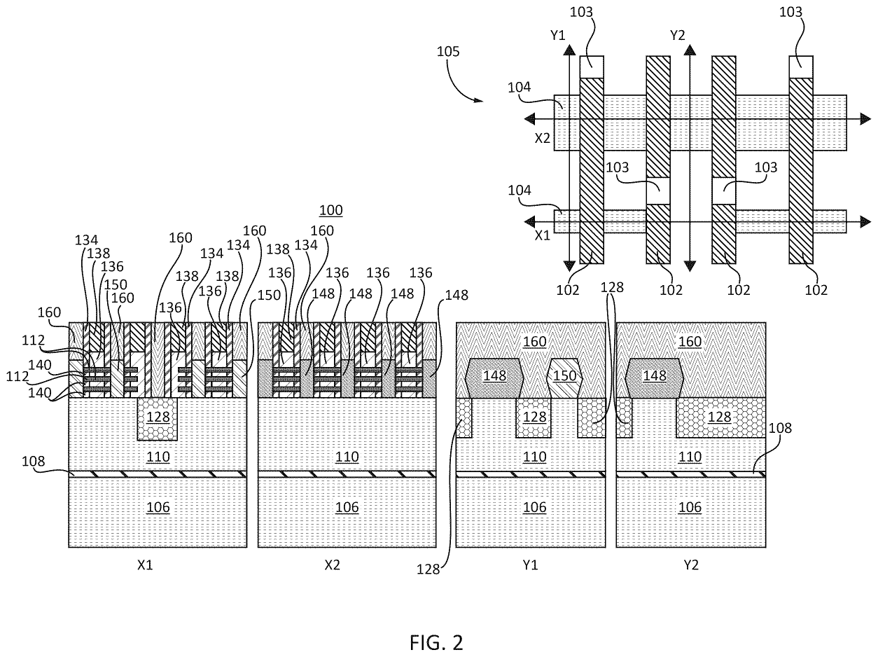

Referring to FIG. 2, devices and methods for manufacturing a nanosheet field effect transistor (FET) device are shown in accordance with embodiments of the present invention. A wafer 100 includes a substrate 106 on which a semiconductor device will be fabricated. FIG. 1 depicts views X1, X2, Y1 and Y2 taken at corresponding sections in inset 105. Inset 105 shows gate lines 102 and active regions lines 104 for reference. Corresponding X1, X2, Y1 and Y2 views are depicted throughout FIGS. 1-13. Active region lines 104 represent source/drain (S/D) regions for transistor devices to be formed, and gate lines 102 are represented for such transistor devices. Gate lines include gate cuts 103. Transistor channels are formed on the active region lines 104 below the gate lines 102. It should be understood that while a nanosheet structure with nanosheet devices or forksheet devices is described and shown, other types of field effect transistor structures and device structures are contemplated in accordance with embodiments of the present invention.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal of the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A layer stack or stacks are applied to or formed on the semiconductor layer 110. In an embodiment, one or more nanosheets (NS) are applied to the semiconductor layer 110. The nanosheet includes alternating layers of different semiconductor materials. The alternating layers can be epitaxially grown using different chemistries to form layers having different properties. In an embodiment, each of the channel layers 112 of semiconductor materials are processed to form transistor channels. The channel layers 112 can include Si although other semiconductor materials can be employed. The layers between the channel layers 112 can include SiGe.

The nanosheet, which includes channel layers 112 can be patterned to expose and etch the semiconductor layer 110. In an embodiment, a hard mask (not shown) may be formed by blanket depositing a layer of hard mask material, providing a patterned photoresist on top of the layer of hard mask material, and then etching the layer of hard mask material to provide the hard mask pattern for etching the nanosheet. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Openings formed through the nanosheet can be etched, for example, by an anisotropic etch process, such as a reactive ion etch (RIE) or an ion beam etch (IBE). The etch process can be employed to further etch the semiconductor layer 110 to form shallow trenches therein in accordance with the openings. Shallow trench isolation (STI) regions or STIs 128 are formed in these etched trenches. STIs 128 can be formed by depositing dielectric material, such as, e.g., SiO₂, SiOₓN_{y}, SiCO or other suitable compounds. STIs 128 can be deposited using chemical vapor deposition (CVD), although other deposition methods can be employed. The STIs 128 can then be etched, e.g., by RIE, to a level of the semiconductor layer 110.

A dummy gate material for dummy gates (not shown) is blanketed over the wafer 100 followed by a blanket deposition of a hard mask material to later form a patterned hard mask, e.g., by using photolithographic patterning. The dummy gate material can include a polysilicon, amorphous Si or other selectively removeable material. The dummy gates are formed by etching followed by the formation of spacers 134 which can include an oxide, such as silicon dioxide, although other dielectric materials can be employed. Inner spacers 140 are formed and include a deposited dielectric material. In an embodiment, the inner spacers 140 are formed in place of laterally recessed portions of the nanosheet.

An epitaxial growth process is performed to form source and drain (S/D) regions 148 and 150. S/D regions 148 and 150 are employed to form transistors. S/D regions 148 and 150 can include Si or SiGe and include faceted surfaces when epitaxial growth is not confined. In one embodiment, the S/D regions 148 and 150 can be designated as N-type or P-type devices. The P-type and N-type devices can have different materials selected for the S/D regions 148 and 150. For example, if the S/D regions 148 and 150 include N-type devices than the S/D regions 148 and 150 can include Si. In another example, if the S/D regions 148 and 150 include P-type devices than the S/D regions 148 and 150 can include SiGe. The S/D regions 148 and 150 can be appropriately doped during the formation of the S/D regions 148 and 150 by epitaxial growth. For example, the S/D regions 148 and 150 can be doped by introducing p dopants (e.g., B, Ga, etc.) during epitaxial formation. Similarly, the S/D regions 148 and 150 can be doped by introducing n dopants (e.g., P, As, etc.) during epitaxial formation. In other embodiments, P-type and N-type devices can be formed adjacent to one another. For example, S/D region 148 can include an N-type region while S/D regions 150 can include a P-type region. Processing would include forming one device type and then the other device type by employing block masks or other structures to protect each device during processing of the other.

A dielectric layer 160, such as, e.g., an interlevel dielectric layer (ILD) is formed on the wafer 100. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using chemical vapor deposition (CVD), although other deposition methods can be employed. The dielectric layer 160 is then planarized, e.g., by chemical mechanical polishing (CMP) to level material of the dielectric layer 160.

The gate cuts 103 are formed by patterning and etching the dummy gates (not shown) by depositing a dielectric material therein to separate portions of gate lines into smaller segments. The dummy gates are removed by etching. The removal of the dummy gates exposes the channel layers 112. A high dielectric constant (high-K) gate dielectric (not shown) is formed on the channel layers 112 followed by a gate metal fill to form gate conductors 136. This process is known as a High-K Metal Gate (HKMG) process to form a gate structure for selectively activating FETs. Self-aligned caps 138 are formed on the gate conductors 136. Self-aligned caps 138 include a dielectric material deposited and planarized over the gate conductors 136.

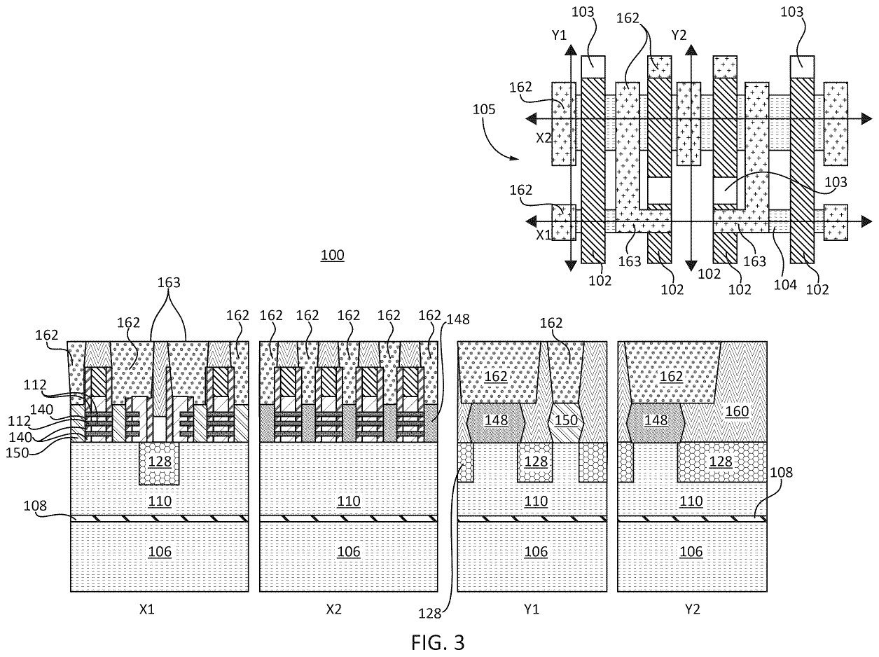

Referring to FIG. 3, middle of the line (MOL) contacts 162 and contact straps 163 are formed to make connections with the S/D regions 148 and 150. Trenches or holes are formed in the dielectric layer 160. The trenches or holes expose the underlying active materials for the S/D regions 148 and 150.

In some embodiments, a silicide liner, such as Ti, Ni, NiPt is deposited first over the S/D regions 148 and 150, then a diffusion barrier can be formed in the trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form the contacts 162, and contact straps 163.

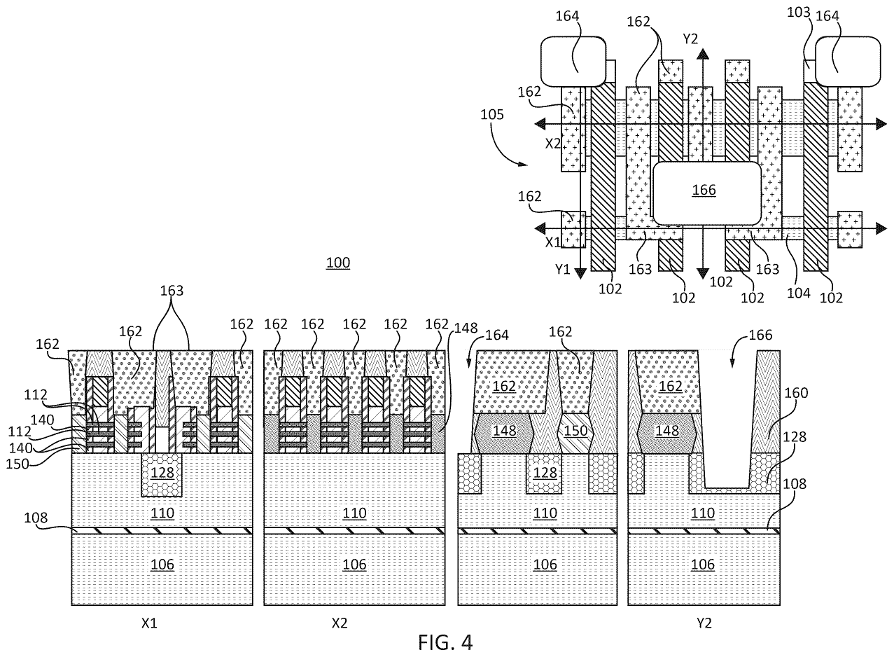

Referring to FIG. 4, trenches 164, 166 or holes are formed in the dielectric layer 160 and STI 128 and through portions of contacts 162. The trenches 164, 166 or holes are etched in accordance with an etch mask (not shown) through and down into the STI 128. The etch process can include a RIE process or other anisotropic etch process.

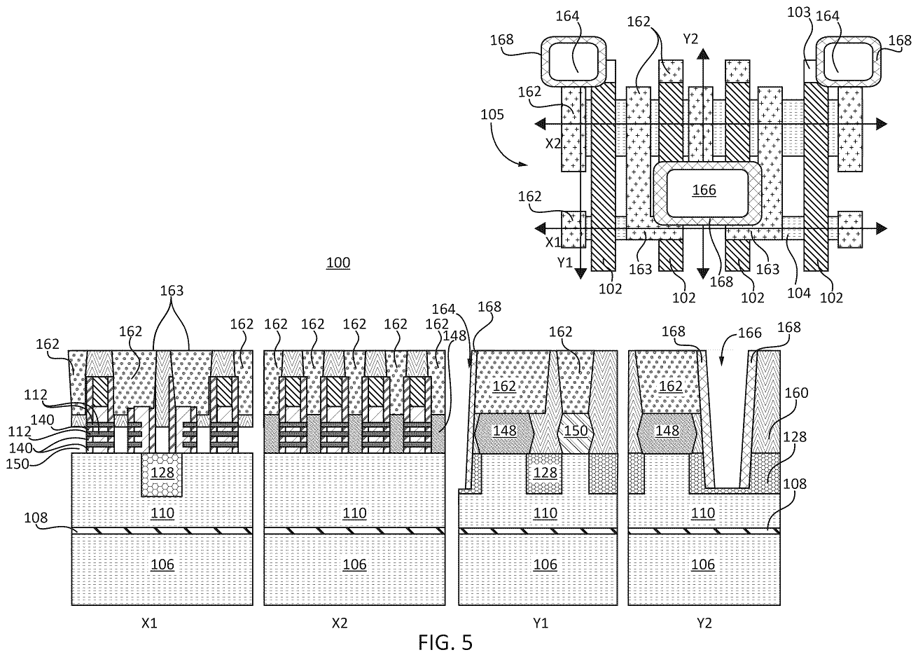

Referring to FIG. 5, a spacer layer 168 is formed in the trenches 164 and 166. The spacer layer 168 includes conformally deposited dielectric materials, such as a nitride or an oxide. The spacer layer 168 can be deposited and removed from horizontal surfaces by an etch process, e.g., RIE. In this way, the spacer layer 168 occupies side walls of the trenches 164, 166.

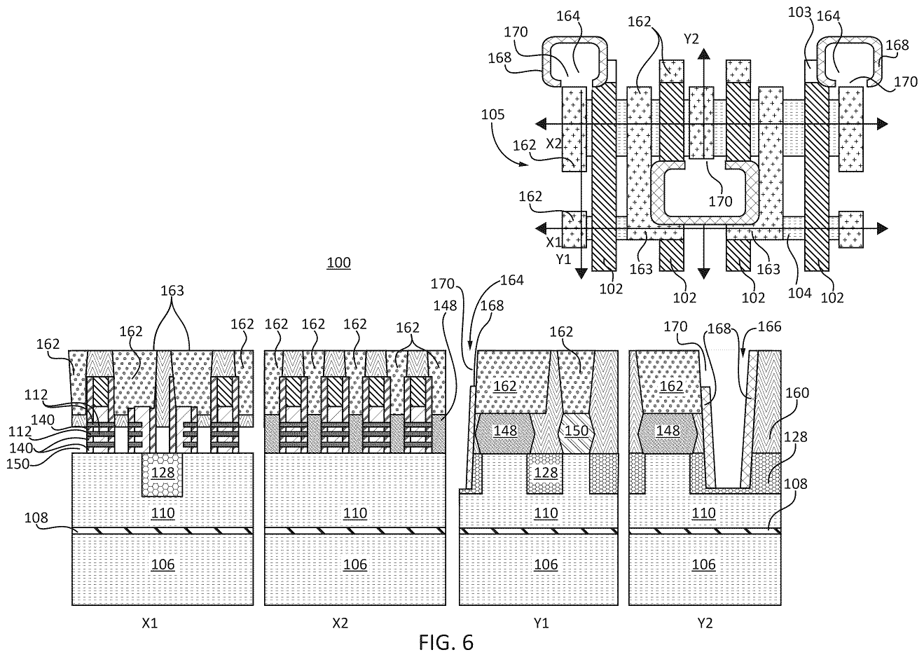

Referring to FIG. 6, a patterned etch is performed to open up portions of the spacer layer 168 to form contact connection ports 170. The patterned etch can employ a patterned etch mask (not shown) with openings at positions for the contact connection ports 170. The spacer layer 168 is selectively removed at these locations to form the contact connection ports 170. The patterned etch also exposes the contacts 162 which had portions etched during the formation of the trenches 164 and 166.

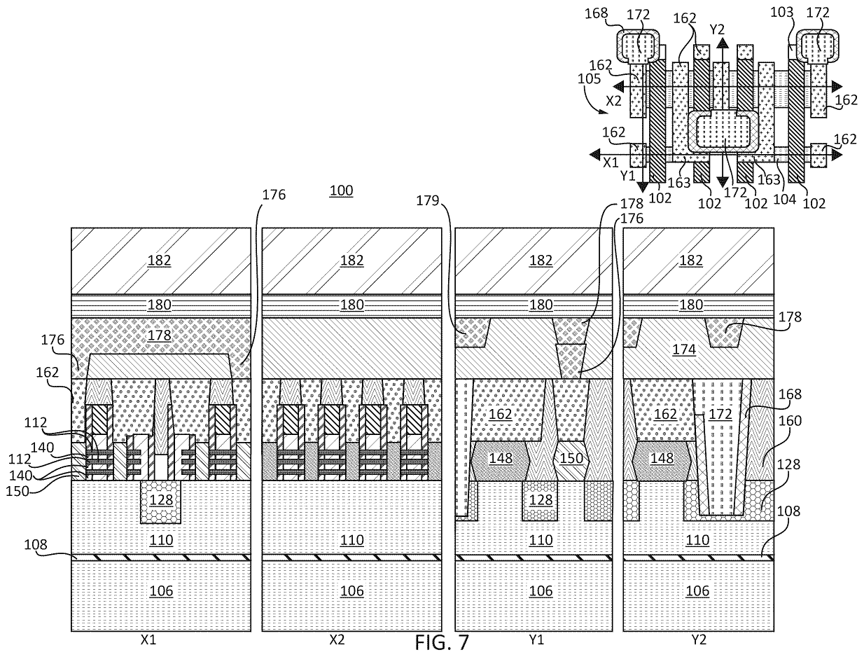

Referring to FIG. 7, a conductive fill is performed to fill the trenches 164, 166 on top of the spacer layer 168. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form vias 172. The vias 172 connect to the contacts 162 formed adjacent to the vias 172.

A dielectric layer 174 is formed over the wafer 100. The dielectric layer 174 can include any suitable material, e.g., the materials described for dielectric layer 160. The dielectric layer 174 is patterned to form vias 176 and further extended in thickness to form metal lines 178, 179. Metal lines 178 can include power rails for carrying a supply voltage, e.g., a position supply voltage (VDD). In an embodiment, metal line 179 can include a word line. Word lines are employed in memory devices to, e.g., address memory cells. The word lines can include, e.g., gate structures, which run orthogonally to bit lines in the memory device. It should be understood that any number of metal layers and dielectric layers can be employed in constructing a frontside of a semiconductor device from wafer 100.

Frontside processing continues with the formation of back end of the line (BEOL) layer 180, which can include metal structures and dielectric layers to complete the frontside of the device and provide electrical access to the FET devices formed. A carrier wafer 182 can be bonded to the BEOL layer 180. The carrier wafer 182 provides support and transportability to the wafer 100 for further processing which includes flipping the wafer 100 and removing portions of a backside of the device.

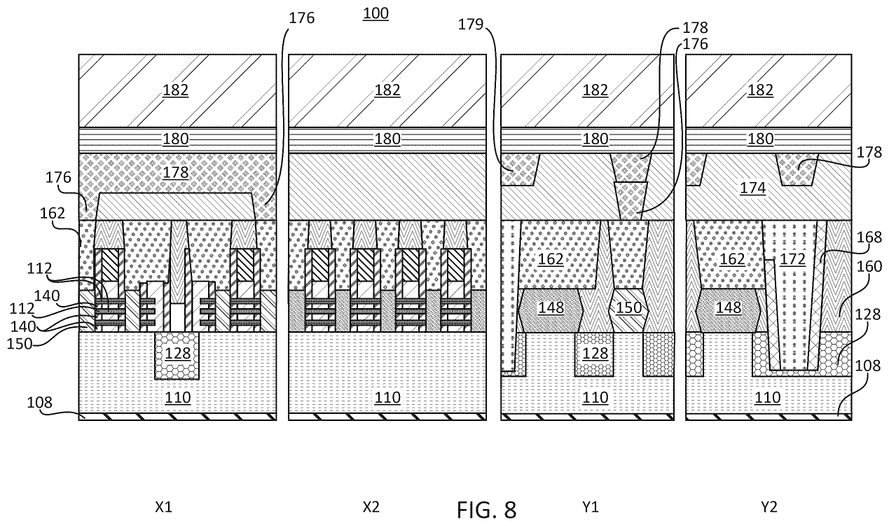

Referring to FIG. 8, to continue processing, the wafer 100 can be flipped to process features on the backside thereof. However, for clarity and consistency, the wafer 100 will be shown in the FIGS. in a same orientation as previously described with continued and consistent reference to front/back and top/bottom. The substrate 106 is removed from the backside of the wafer 100. The substrate 106 can be removed by an etch process that stops on the etch stop layer 108.

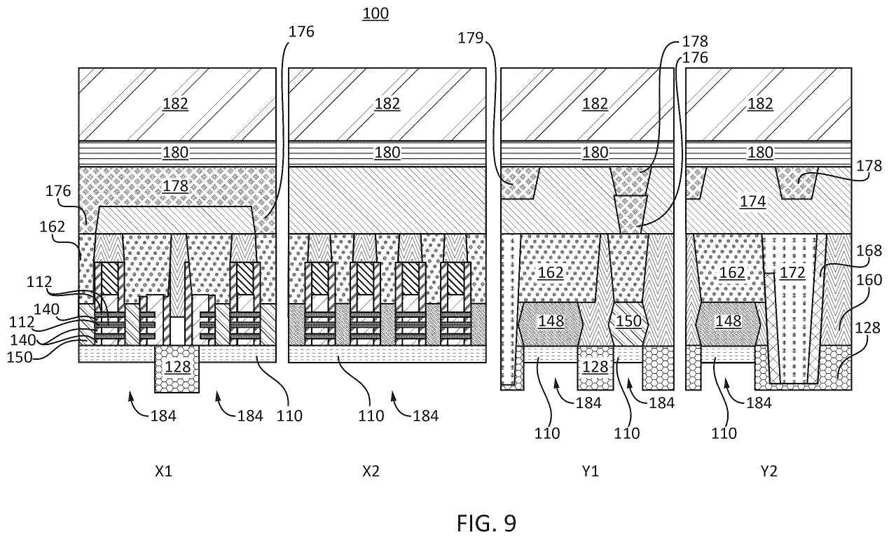

Referring to FIG. 9, the etch stop layer 108 is then removed by an etch process. In an alternate embodiment, a CMP process can be employed. With the removal of the etch stop layer 108, the semiconductor layer 110 is exposed. The semiconductor layer 110 is patterned and partially removed or recessed by a timed etch process that selectively removes the material of the semiconductor layer 110 relative to the STI 128 in regions 184.

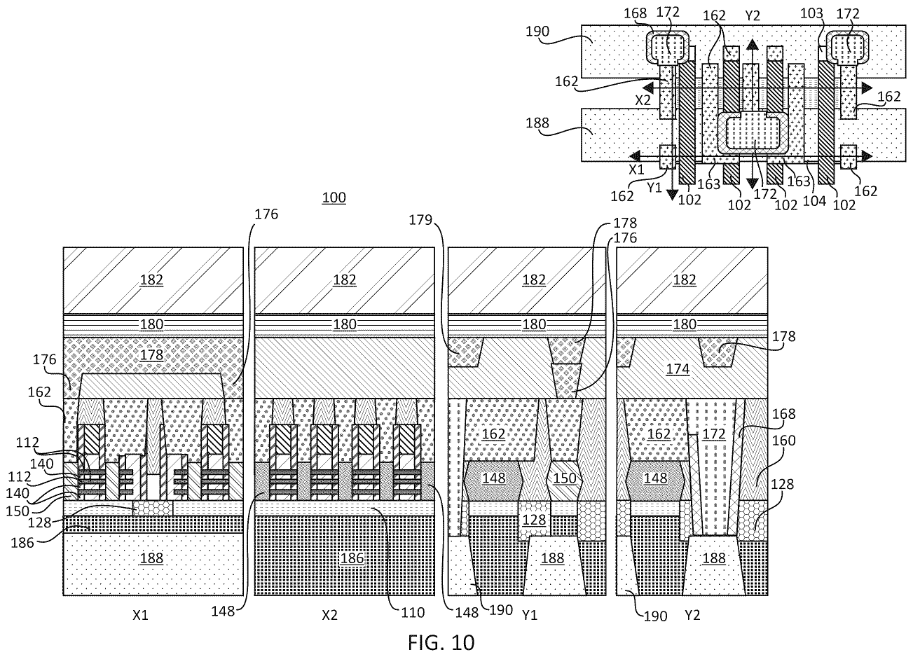

Referring to FIG. 10, a dielectric layer 186 (e.g., a backside interlayer dielectric (BILD)) is formed in the regions 184 (FIG. 9). The dielectric layer 186 can include any suitable material, e.g., the materials described for dielectric layer 160. After planarization, the dielectric layer 186 is patterned and etched to open up trenches for the formation of metal structures. For example, power rails 190 and bit lines 188 can be formed.

The trenches can be patterned using photolithographic patterning techniques to create an etch mask to etch the trenches or holes with an anisotropic etch., e.g., RIE. The formation of the trenches exposes the vias 172.

A diffusion barrier can optionally be formed in the trenches prior to a conductive fill. The diffusion barrier can include, e.g., TiN, TaN, or similar materials. A conductive fill is performed to fill the trenches. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the power rails 190 and bit lines 188. In an embodiment, the power rail 190 can include a negative power supply voltage, e.g., VSS.

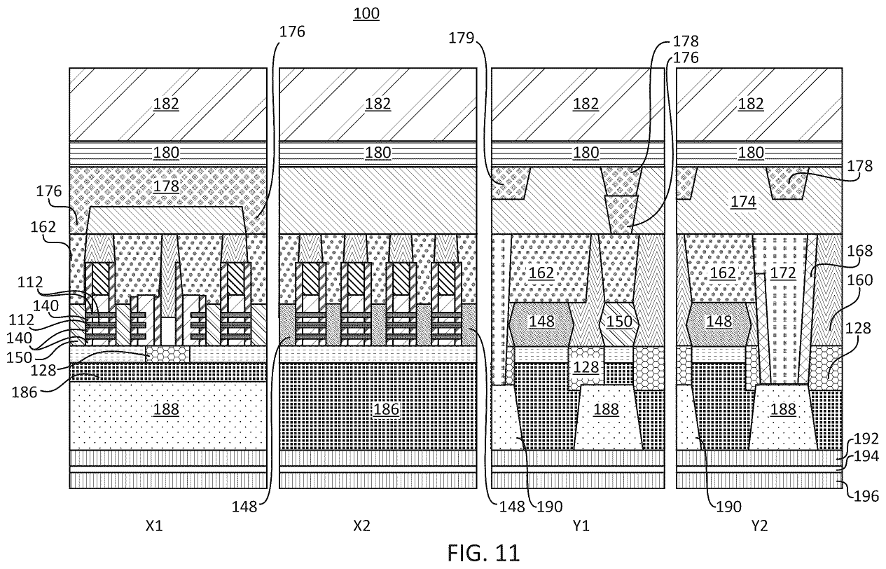

Referring to FIG. 11, a blanket deposition of MIM capacitor materials is performed. A MIM capacitor stack includes a dielectric material sandwiched between two metal layers. The metal layers form electrodes of the MIM capacitor. A blanket deposition process deposits a metal layer 192 for a first capacitor electrode. A next blanket deposition deposits a dielectric layer 194 on the metal layer 192. Another blanket deposition process deposits a metal layer 196 for a second capacitor electrode. The metal layers can include any suitable metal materials.

In some embodiments, the metal layers 192 and 196 can include a same metal and in other embodiments the metal layers 192 and 196 can include different metals. The metal layers 192 and 196 can include, e.g., W, Cu, Ru, Mo and alloys or combinations of these and other conductive materials. The blanket deposition process for metal layers can include a sputter deposition, electroplating or other deposition process or processes. The blanket deposition process for the dielectric layer can include any suitable deposition process, such as, e.g., CVD. The dielectric layer 194 can include a high dielectric constant material or materials, such as, e.g., silicon oxide, silicon nitride, silicon oxynitride, hafnium silicate, zirconium silicate, hafnium dioxide, zirconium dioxide or combinations of these and other dielectric materials.

The metal layer 192 is formed on the bit lines 188. The bit lines 188 and the metal layer 192 can include a same material or include a material that limits mass transfer. In an embodiment, a diffusion barrier can be formed between the bit lines 188 and the metal layer 192. The diffusion barrier can include, e.g., TiN, TaN, or similar materials.

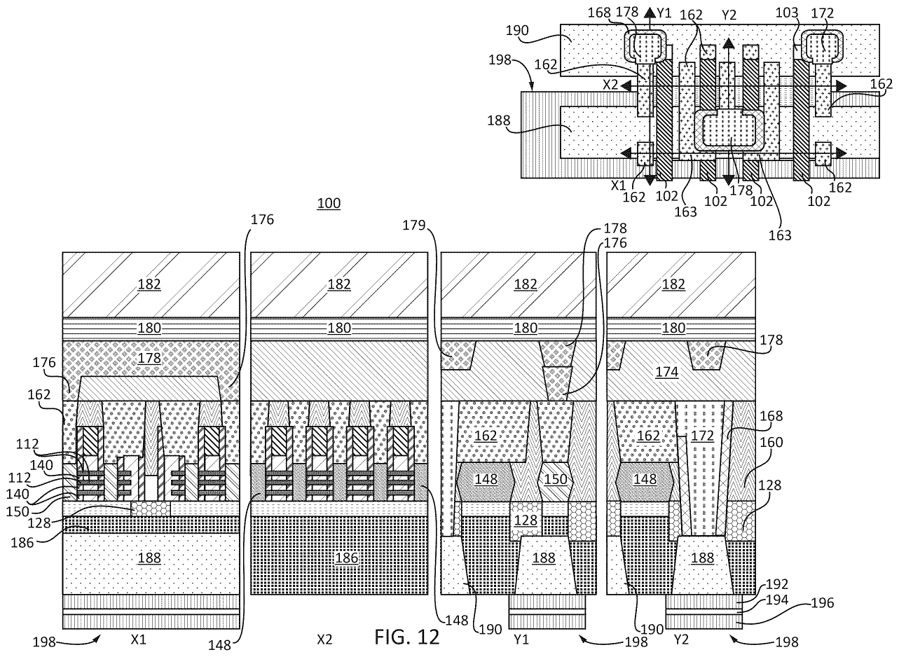

Referring to FIG. 12, the MIM capacitor stack is patterned. Since the MIM stack is blanketed across the wafer, the MIM capacitor 198 can be formed in a variety of shapes and sizes as needed for a particular design. The freedom to customize a size and shape of the MIM capacitor provides versatility and design options without impacting layout area.

In an embodiment, a hard mask (not shown) may be formed by blanket depositing a layer of hard mask material, providing a patterned photoresist on top of the layer of hard mask material, and then etching the layer of hard mask material to provide the hard mask pattern for etching the MIM stack. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process, which is then transferred to the MIM stack by a same or different etch process. The etch process can include a RIE or ion beam etch.

The MIM stack is patterned to form the MIM capacitor(s) 198 across the wafer 100 on its own level. This provides great flexibility in determining the size and shape of the MIM capacitor 198. The backside MIM capacitor 198 and the backside signal line (e.g., bit line 188) can share a footprint (e.g., take up a same projected layout area) or the backside MIM capacitor 198 can extend beyond a footprint of the bit line 188 as depicted in FIG. 11 and FIG. 1.

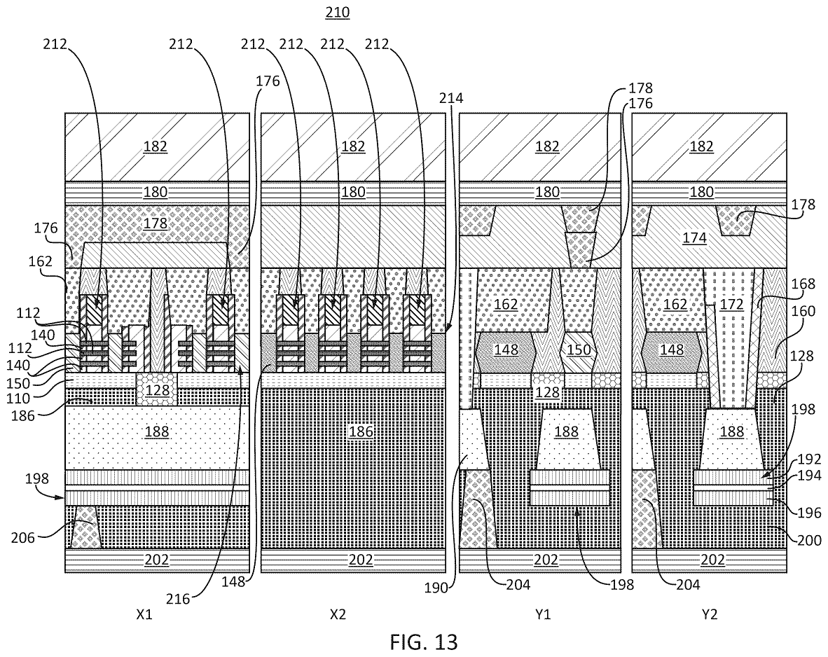

Referring to FIG. 13, processing continues with the formation of a backside interconnect layer 202, which can include metal structures (e.g., vias 204 and backside contacts 206), metal lines and dielectric layers 200 to complete the backside of a semiconductor device 210 and provide electrical access to transistor devices and MIM capacitors 198 formed. The backside interconnect layer 202 is formed on the dielectric layer 200 and backside contacts 206 and vias 204.

The semiconductor device 210 includes field effect transistors (FETs) 214, 216 that use the channel layers 112 to selectively conduct charge between S/D regions connected thereto. The FETs include S/D regions 148, 150, as electrodes, which are connected when the channel layers 112 are activated to conduct by corresponding gates structures 212. The FETs formed by the channel layers 112, S/D regions 148, 150 and the gate structures 212 can be included in SRAM memory cells that each include multiple FETs (e.g., 6, 8, etc.).

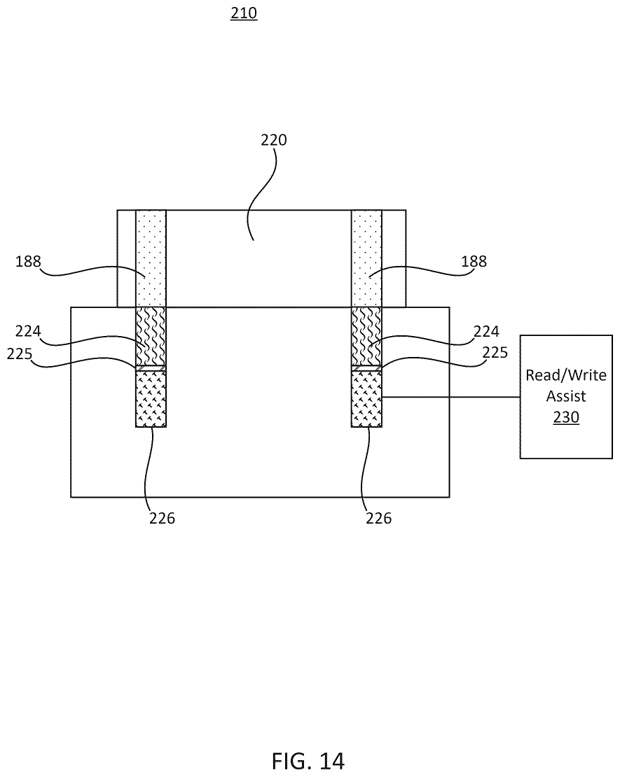

Referring to FIG. 14, a schematic diagram shows the semiconductor device 210 with an SRAM cell 220 having bit lines 188 connected to a first electrode 224 (metal layer 192, FIG. 12) of the MIM capacitor(s) 198. A second electrode 226 (metal layer 196, FIG. 12) is capacitively coupled to the first electrode 224 through a capacitor dielectric 225 (dielectric layer 194, FIG. 12). The second electrode 226 is connected to a read/write assist circuit 230, which provides a power boost to the SRAM cell 220 during read/write operations and especially during write operations.

In accordance with embodiments of the present invention, the SRAM cell 220 includes a backside signal line (e.g., bit line 188) which can be electrically coupled to the backside MIM capacitor 198 to provide performance improvements including writability enhancement by improving effective resistance-capacitance (RC). Further writability enhancement can be achieved by modulation of signals on the bit line 188 through capacitive coupling to the MIM capacitor 198 which connects to the read/write assist circuit 230. The backside MIM capacitor 198 and backside signal line (e.g., bit line 188) reduce pressure density on metal layer interconnects on a frontside of the semiconductor device 210 and reduce or eliminate the risk of short circuits (shorts).

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or backside interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a memory cell having a frontside and backside;
a backside signal line connected to the memory cell on the backside; and
a backside metal-insulator-metal (MIM) capacitor on the backside and having a first electrode connected to the backside signal line and a second electrode connected to an assist circuit that electrically boosts access operations of the memory cell.

2. The semiconductor device as recited in claim 1, further comprising electrical connections to the backside MIM capacitor through the backside to reduce a density of metal structures on the frontside.

3. The semiconductor device as recited in claim 1, wherein the backside MIM capacitor is disposed directly on the backside signal line.

4. The semiconductor device as recited in claim 3, wherein the backside MIM capacitor and the backside signal line share a footprint.

5. The semiconductor device as recited in claim 3, wherein the backside MIM capacitor extends beyond a footprint of the backside signal line.

6. The semiconductor device as recited in claim 1, wherein the backside signal line includes a bit line.

7. The semiconductor device as recited in claim 1, wherein the backside signal line and a backside power line share a same level on the backside of the semiconductor device.

8. A semiconductor device, comprising:
a memory cell having a frontside and backside, the memory cell including a plurality of field effect transistors, the plurality of field effect transistors including source/drain regions;
source/drain contacts connected to the source/drain regions;
a via laterally connected to a source/drain contact and extending to the backside;
a backside signal line connected to the via on the backside; and
a backside metal-insulator-metal (MIM) capacitor on the backside and having a first electrode connected to the backside signal line and a second electrode connected to an assist circuit that electrically boosts access operations of the memory cell.

9. The semiconductor device as recited in claim 8, further comprising electrical connections to the backside MIM capacitor through the backside to reduce a density of metal structures on the frontside.

10. The semiconductor device as recited in claim 8, wherein the backside MIM capacitor is disposed directly on the backside signal line.

11. The semiconductor device as recited in claim 10, wherein the backside MIM capacitor and the backside signal line share a footprint.

12. The semiconductor device as recited in claim 10, wherein the backside MIM capacitor extends beyond a footprint of the backside signal line.

13. The semiconductor device as recited in claim 8, wherein the backside signal line includes a bit line.

14. The semiconductor device as recited in claim 8, wherein the backside signal line and a backside power line share a same level on the backside of the semiconductor device.

15. A semiconductor device, comprising:
a memory cell having a frontside and backside, the memory cell including a plurality of field effect transistors, the field effect transistors including source/drain regions;
source/drain contacts connected to the source/drain regions;
a first via laterally connected to a source/drain contact and extending to the backside;
a bit line connected to the first via on the backside;
a second via laterally connected to another source/drain contact and extending to the backside;
a backside power line connected to the second via on the backside on a same level as the bit line; and
a backside metal-insulator-metal (MIM) capacitor on the backside and having a first electrode connected to the bit line and a second electrode connected to an assist circuit that electrically boosts access operations of the memory cell.

16. The semiconductor device as recited in claim 15, further comprising electrical connections to the backside MIM capacitor through the backside to reduce a density of metal structures on the frontside.

17. The semiconductor device as recited in claim 15, wherein the backside MIM capacitor is disposed directly on the bit line.

18. The semiconductor device as recited in claim 15, wherein the backside MIM capacitor and the bit line share a footprint.

19. The semiconductor device as recited in claim 15, wherein the backside MIM capacitor extends beyond a footprint of the bit line.

20. The semiconductor device as recited in claim 15, wherein the semiconductor device includes a static random access memory.
